(19) United States
(12) Patent Application Publication
(10) Pub. No.: US 2011/0038694 A1
(43) Pub. Date: Feb. 17, 2011

(54) SEMICONDUCTOR DIE SORTER FOR WAFER LEVEL PACKAGING

(76) Inventor: Hun Sniah Khoo, Penang (MY)

Correspondence Address: Pintas LLC, P.O.Box 190943, Boise, ID, 83719, US

(21) Appl. No.: 12/988,149

(22) PCT Filed: Apr. 10, 2009
(86) PCT No.: PCT/MY09/00051

§ 371 Date: Oct. 15, 2010

(30) Foreign Application Priority Data
Apr. 18, 2008 (MY) PI 20081146

(51) Int. Cl. H01L 21/677; H01L 21/68; H01L 21/683

(52) U.S. Cl. 414/222.01

(57) ABSTRACT

A die sorter for sorting a semiconductor dice is provided. The die sorter comprising of a rotary turret module (19) with indexing mechanism for die sorting; the rotary turret module (19) is further coupled with a motor for generating rotating movements. A plurality of flipper modules (20) with rotary actuating means (72) is coupled with the rotary turret module (19) for enabling the flipping process of the flipper module (20). In one embodiment, a plurality of shutter openers (55) are operatively coupled to the flipper module (20) to move the cavity shuttle (93) to open position for pick and place operation of die. In one preferred embodiment, a plurality of cavity releasing means (57) are operatively coupled to the flipper module (20) to unlock the cavity holder (74) prior to activate the flipping mechanism, whereby the cavity releasing means (57) is a cam mechanism which is mounted on the rotary turret module (19). The flipper module (20) further comprises of a cavity lock (75) to secure the flipper module (20) in horizon position as well to prevent it from drifting. In one preferred embodiment, the shutter openers (55) are operatively coupled to a motor whereby with a single rotating movement of the motor either clockwise or counter clockwise will open the cavity shuttle (93) will be open.

### FIELD OF THE INVENTION

This invention relates to semiconductor manufacture and more particularly to a die sorter for manufacturing known good die.

### BACKGROUND ART

The present invention relates to the field of semiconductor back end process for Wafer Level Packaging (WLP), category as bare wafer die, bump die or leadless package sorting in wafer ring form. One of the widely adopted methods during manufacturing of semiconductor dice is sorting bare and bump die's and leadless packages from a wafer ring or other platform. During a typical semiconductor back end manufacturing process of WLP die's and leadless packages, batch of dies and packages are formed in a round wafer of semiconductor material. Towards the end of the manufacturing process, the round wafer is placed on a wafer ring with Mylar or the like. This wafer ring is then loaded to a dicing machine to cut these dies/packages apart. During the fabrication and/or sawing process, which is very critical and delicate, individual dice may be damaged or defective. To prevent shipment or usage of defective dice, each of the dice is tested or probed to determine the level of functionality of the die level before it is transfer to the next stage of the assembly process. The die sorting, which can be in-situ with the testing, sorts the die identified from the testing step. For example, testing may identify a die/package as “good” or “bad”, depending on the level of performance required by the die/package. To save the cost of manufacturing, the direction of the industry is moving towards with Bump Die which, in turn, will produce the integrated circuits at smaller footprint with cost reduction.

The die sorting is usually performed with equipment called a die sorter. The die sorter typically receives a wafer ring containing the dice to be sorted. Individual die/package are then selected from the wafer ring and placed into an output carrier. Conventional Die Sorter include a loader portion & an output portion, they are fully automatic and process the wafers in lots of 25 or more. However, because the output carriers are different (e.g., different sizes, die trays, and/or handling procedures), the die sorter needs to be flexible to accommodate the different output carriers. Thus, die sorters should be able to be changed (e.g., mechanically and/or to software) each time a different output carrier is used to adjust for those differences. Typically, the wafers are transported in Cassettes and placed in the loader portion for die sorting. A wafer handler load each wafer ring sequentially from the storage cassettes to a pre-aligner or expander, where the wafer ID in barcode format or the like is scanned and mapping file is loaded from the host. The wafer Mylar is then to be expanded by mechanical means, the expander stage approximately moved the wafer ring to the center of pick and place station. The wafer ring is then to be pre-oriented by locating the flat or other physical marks such as notch with vision aids; the orientation is coordinate to suit the X-Y stage motion for die sorting.

The conventional pick and place approach has a pick arm to pick the die from expanded ring synchronize with the plunger motion beneath the wafer ring, the pick arm has a permanent flipping mechanism to flip the die/package after picking the die/package from wafer ring and transfer the die/package to another pick arm which will placed the die/package into the carrier tape. Conventional die/package sorter proposed or utilizes Cameras for quality inspection of the bump side surface before picking up the die/package from wafer ring or while it is on the first pick arm and inspect the other surface after placing the die/package into carrier tape pocket, there is limitation with this approach as additional mechanism or the like has to be in place to pick the defected die/package from carrier tape and lately replace with a good die/package, this will force the machine to stop normal operation during this replacement and effected the UPH.

Further limitation with this conventional pick & place operation is there will be limitation to expand or enhance the vision capability to meet the industry expectation when the requirement is getting higher due to the die/package size and inspection criteria.

Another limitation with this conventional approach is the operation is in serial sequences, the wafer change over time is longer because a new wafer ring could not be loaded and preloaded the mapping file before the wafer in process is completed sorting operation and returned to cassette.

### SUMMARY OF THE INVENTION

The present invention provides a die sorter apparatus and method therefore. According to one aspect of the present invention, a die sorter utilizes wafer ring change track and flipper mechanism on rotary turret approach. The flipping feature could be activated or deactivated depend on the manufacturing requirement; multiple vision could be facilitate on multiple station to archive specific inspection criteria to meet industry needs. All these processes are process concurrently in parallel and thus it will not induce additional cycle time for adding in new feature.

According to one embodiment, the loader portion of the sorter included the wafer ring quick change track system operate independently from the pick and place operation. According to one embodiment of the present invention, the design of Wafer Ring Quick Change System (WQCS) reduced the wafer ring change over time. A new wafer could be loaded into the WQCS and wafer ID could be scanned & pre-loaded the mapping file from host at this standby position while a wafer is in sorting operation, upon completion of sorting, it will be transferred back to WQCS and the standby wafer will be loaded to the expander for sorting.

According to another embodiment of the present invention, the pick and place operation utilizes rotary turret with 12 stations, the total number of station could be reduce or increase depend on application requirement. Each individual station is assigned to perform specific function, such as, die input, die output, die reject output, 3D bump inspection, surface quality inspection, die flipping and many other visual inspection tasks of quality check. With this rotary turret concept, each station process simultaneously in parallel. The flipper is an unique design with shuttle plate on both side of the cavity unit, die/package are placed in the cavity pocket and protect by this shuttle plate to prevent die drop out or fly off when the rotary turret is indexing. The shuttle plate on top will be trigger open at station where pick & place of die, vision inspection is required.

This invention will be more fully understood in conjunction with the following detailed description taken together with the following drawings.

### BRIEF DESCRIPTION OF THE DRAWINGS

Additional features of the invention will be more readily apparent from the following detailed description and claims when taken in conjunction with the drawing in which:

FIG. 1 a is the top plan view of an automatic wafer die sorter in accordance with the invention;

FIG. 1b is the top plan view of location for die package quality vision inspection

FIG. 2a is isometric view of Wafer Ring Quick Change System;

FIG. 2b is side plan view of Wafer Ring Quick Change System;

FIG. 3 is the process flow chart of Wafer Ring Quick Change System;

FIG. 4a is the isometric view of main turret system in accordance with the invention;

FIG. 4b is the top plan view of main turret system in accordance with the invention;

FIG. 5 is the isometric view of flipper module in accordance with the invention;

FIG. 6a is the isometric view of flipper actuator unit in accordance with the invention;

FIG. 6b is the side plan view of flipper actuator unit in accordance with the invention;

FIG. 7a is the isometric view of flipper cavity unit in accordance with the invention;

FIG. 7b is the side plan view of flipper cavity unit in accordance with the invention.

### DETAILED DESCRIPTION OF THE PREFERRED EMBODIMENTS

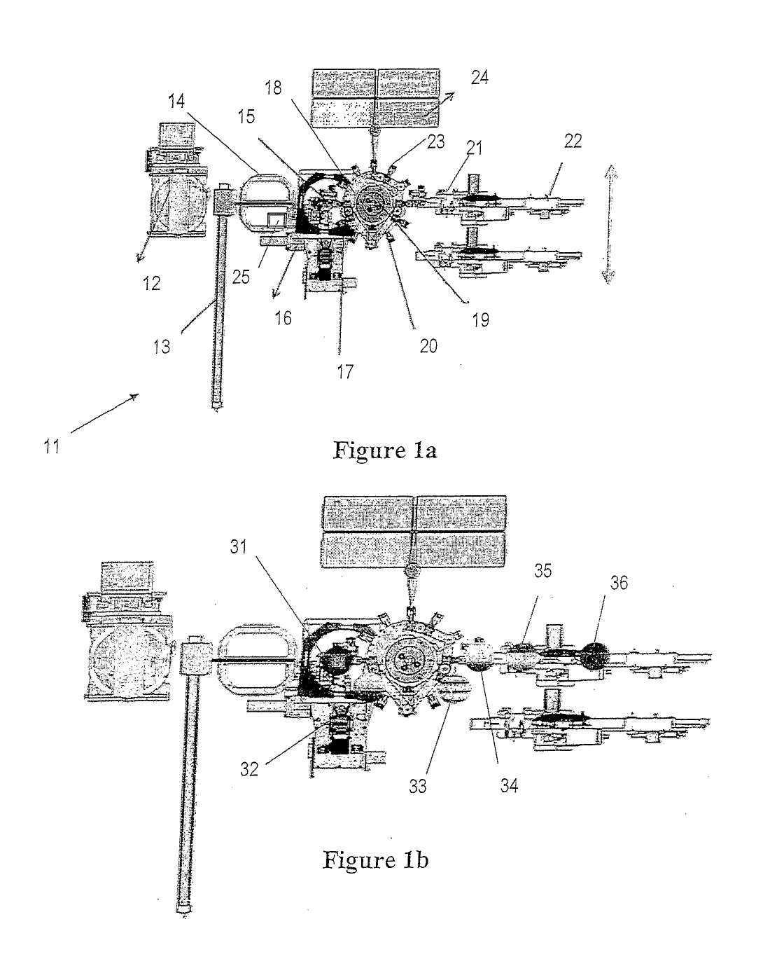

FIG. 1a shows the overall arrangement of a die sorter (11), according to one aspect of the present invention. In one preferred embodiment, the loader portion of the die sorter (11) which is a cassette elevator (12) consist of motorize vertical axis to index a wafer cassette in vertical direction. According to one preferred embodiment of the present invention, the design of Wafer Ring Quick Change System (WQCS) (14) reduces the wafer ring change over time. The wafer handler (13) loads each wafer sequentially from the wafer cassette to the upper track (43) of the WQCS (14), the wafer ID will be then captured with a first camera (25), which is onboard the WQCS (14) to read the wafer ID such as barcode of the wafer. The system will then load the wafer mapping file from a host system to map the identity as well as the coordinate of individual die of the wafer. The wafer handler (13) will subsequently transfer the wafer into expander station (17), the Mylar which holds the wafer will be expanded and the expander X-Y motion stage (16) moved the wafer approximately under a second camera (31), the wafer center point & first pick die coordinate will be obtain by using the second camera (31) to locate the flat or other physical marks such as notch. The wafer will then be aligned and oriented according to this located coordinate for the picking of first die.

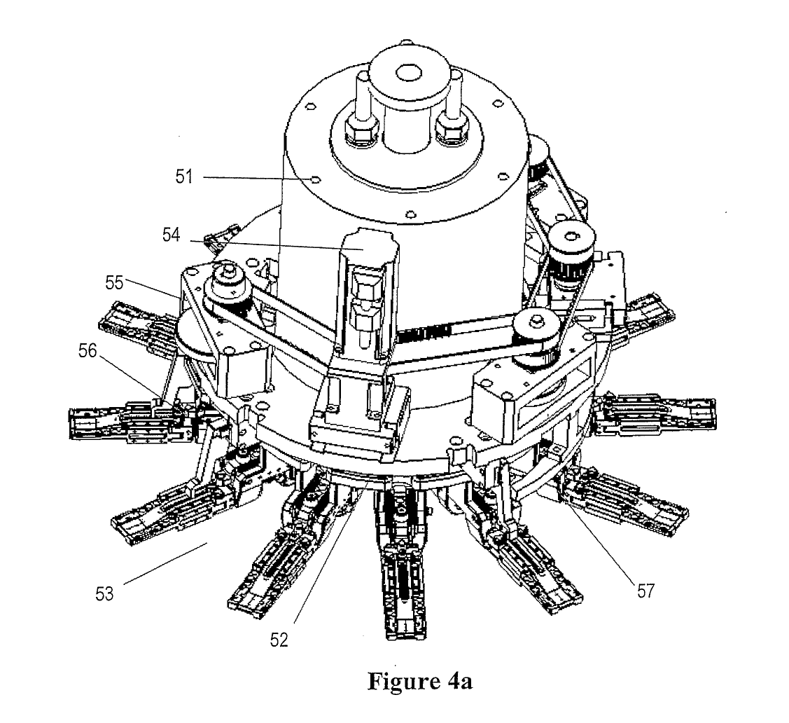

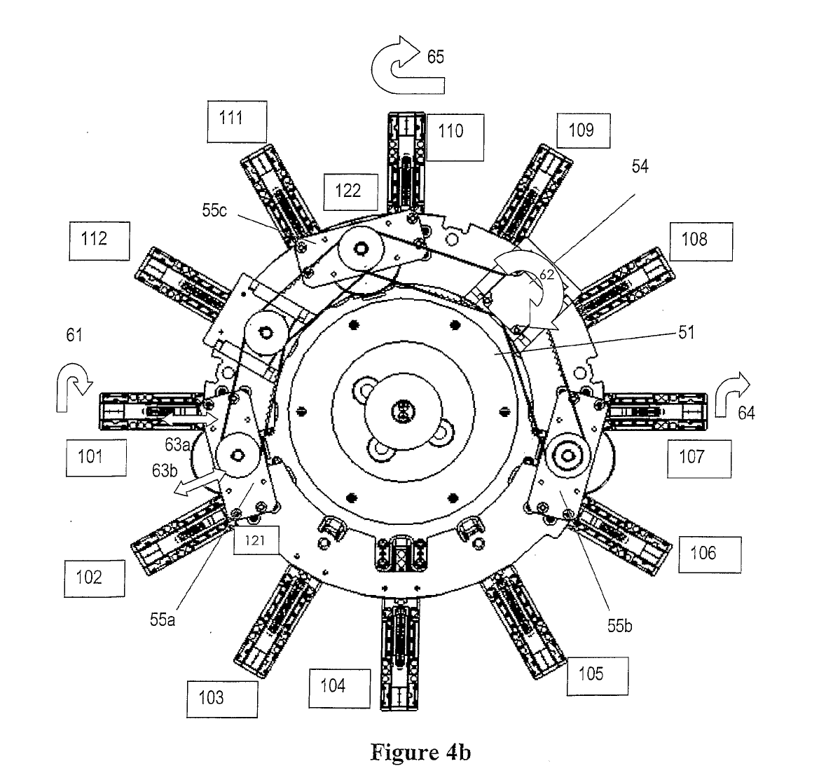

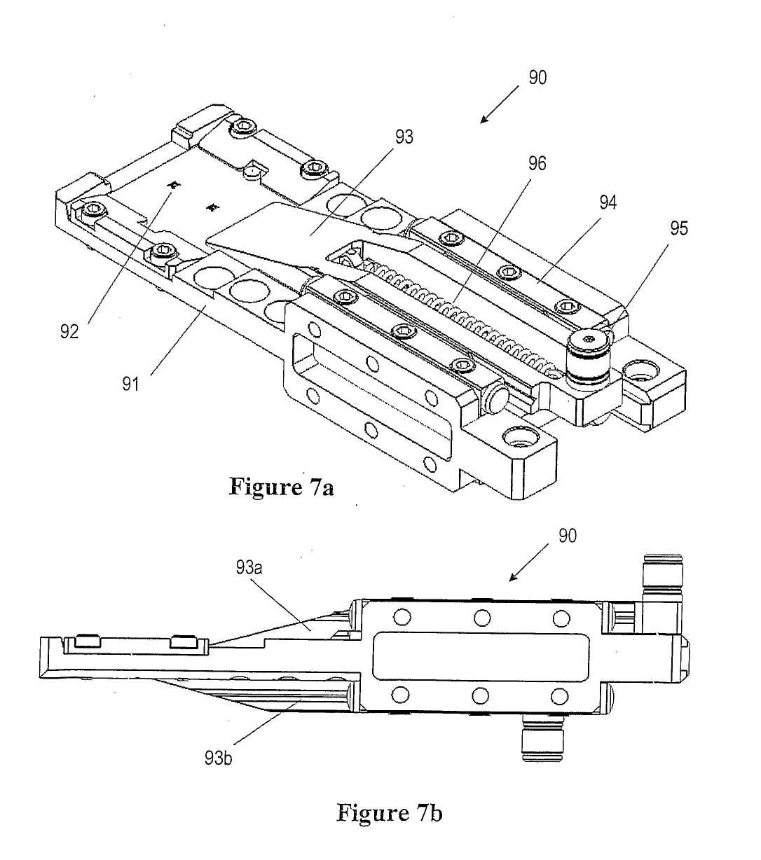

Further referring to FIG. 1 and referring to FIGS. 4b and 7a, a first pick arm (18) will pick the die from expanded ring synchronize with a plunger (15) motion beneath the wafer ring and place it into cavity pocket (92) of a flipper module (20) at first station (101). A rotary turret module (19) will make one index counter clockwise after a top cavity shuttle (93a) closed, a shuttle opener (55) will open the top cavity shuttle (93a) again after the indexing in place to place next die into cavity pocket (92) of the flipper module (20) at first station (101), while a third camera (32) inspection take place at second station (102). Subsequence processes and vision inspection is conducted in parallel at the same time at respective stations (101 to 112).

Good die will be unload to output tape and real module (22) with a second pick arm (21) at the seventh station (107), defected die will be output to a JEDEC tray module (24) with a third pick arm (23) at the tenth station (110).

FIG. 1b shows the location of various camera used for vision inspection for the present invention, in one preferred embodiment of the present invention, the second camera (31) is used for wafer alignment and die coordinate for pick and place operation. The third camera (32) is for die bump and surface quality inspection on the bottom side of the die. A forth camera (33) is for the marking and surface quality inspection of the die on top side. A fifth camera (34) is used to inspect the surface quality on 4 sides of the die. A sixth camera (35) is used to check the die orientation after placing into the carrier tape. A seventh camera (36) is used to inspect the seal quality of the carrier tape. For the third camera (32) and the forth camera (33), it capture the die image after the top cavity shuttle (93a) is triggered opened.

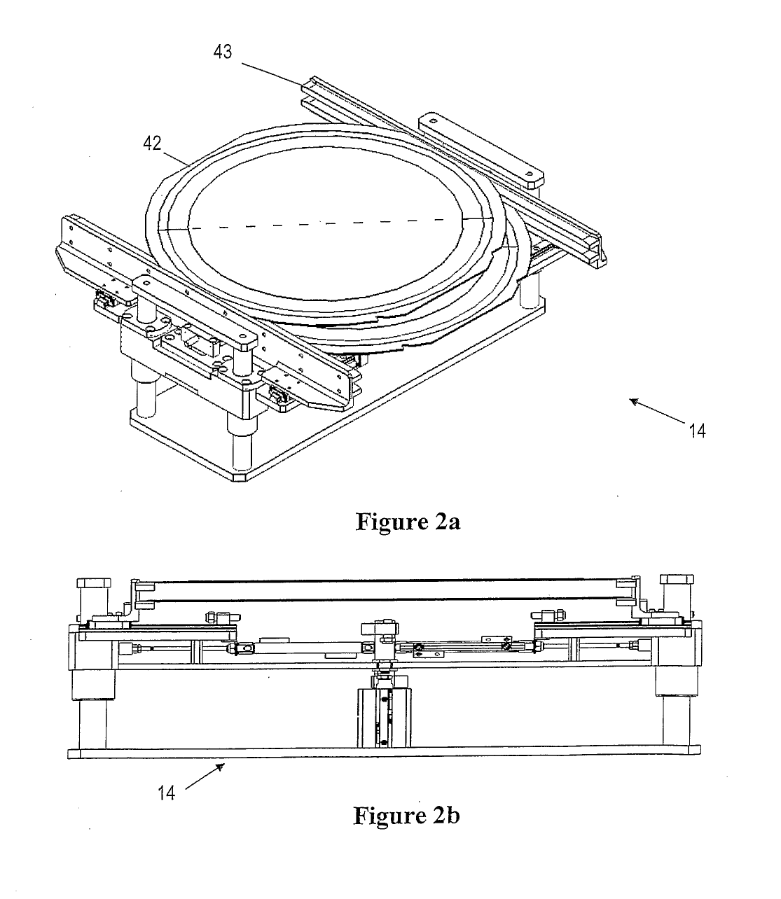

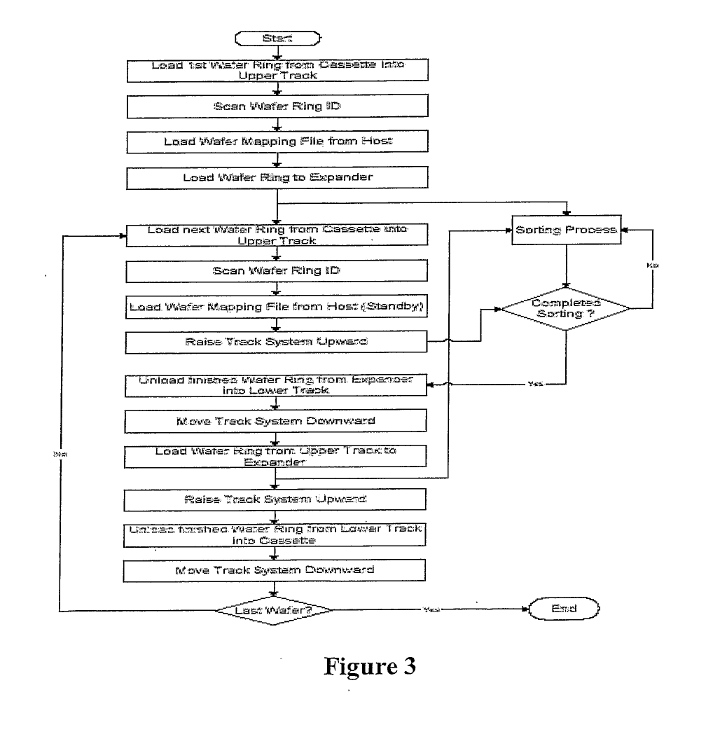

FIG. 2a is isometric view of the Wafer Ring Quick Change System (WQCS) whereas FIG. 2b is side plan view of Wafer Ring Quick Change System (WQCS). In one preferred embodiment of the present invention, FIGS. 2a & 2b is the buffer station for wafer ring (42) loading and unloading between wafer cassette and the expander module. FIG. 3 is the process flow chart of Wafer Ring Quick Change System (WQCS), in one preferred embodiment the first wafer is loaded from the cassette into the upper track (43) and the wafer ring ID which represents the identity of the wafer is subsequently scanned and registered. In one preferred embodiment, the system will then load the wafer mapping file from the host system to map the identity as well as the coordinate of individual die. The wafer handler (13) will subsequently transfer the wafer into the expander station (17) for sort operation. Upon the completion of the sort operation, the wafer is subsequently unloaded from the expander and eventually unloaded. The operation will be repeated until the last wafer is completed.

FIGS. 4a & 4b show the overall design of the rotary turret module (19) which is the core invention makes the die sorter difference from the conventional maker of the industry. In one preferred embodiment of the present invention, the rotary turret module (19) consist a number of flipper modules (20) which is the other invention that make this rotary turret module (19) a superior concept to perform multitasking in synchronize at respective stations while maintain the industry preferred 2 touch approach on pick and place of a die while meeting the cycle time of 240 ms or less per die.

In one preferred embodiment, the module also has 3 shuttle openers (55a, 55b & 55c) link to a motor (54), with single rotating movement of the motor either clockwise or counter clockwise (62), it triggered simultaneously all three shuttle openers (55a, 55b & 55c) which, in turn, moves the top cavity shuttle (93a) at the first station (101), second station(102), sixth station (106), seventh station (107) and tenth station (110) in third linear direction (63a & 63b). In one preferred embodiment, as seen in FIG. 4a and FIG. 7a, each of the shuttle openers (55) has either one or two claw fingers (56) that will hook on the cam follower (95) mounted on the cavity shuttle (93) and leads it to open position when moving linearly inwards. A die is then placed into the cavity pocket (92) from first direction (61), and good die will be transfer out at second direction (64) to carrier tape module, while defected die goes to reject module in forth direction (65).

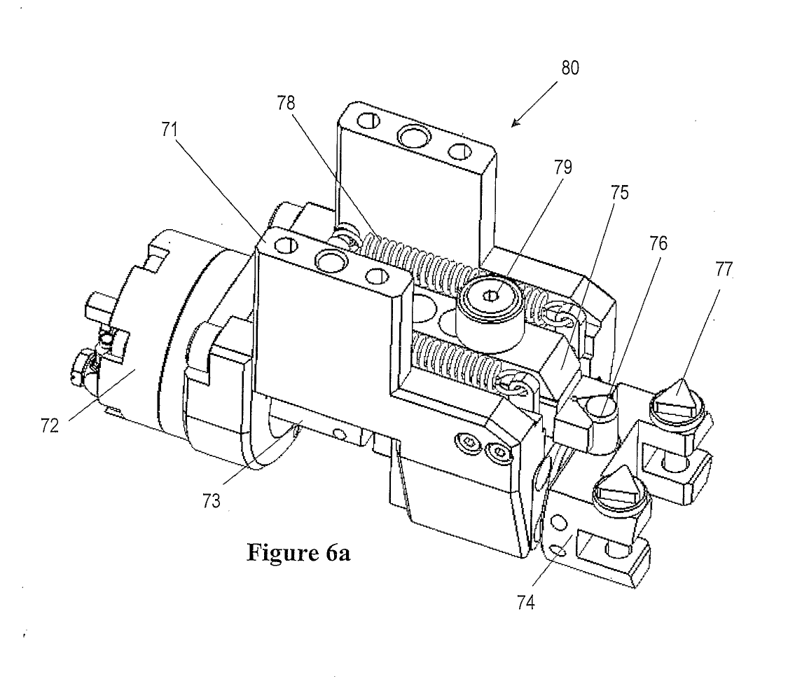

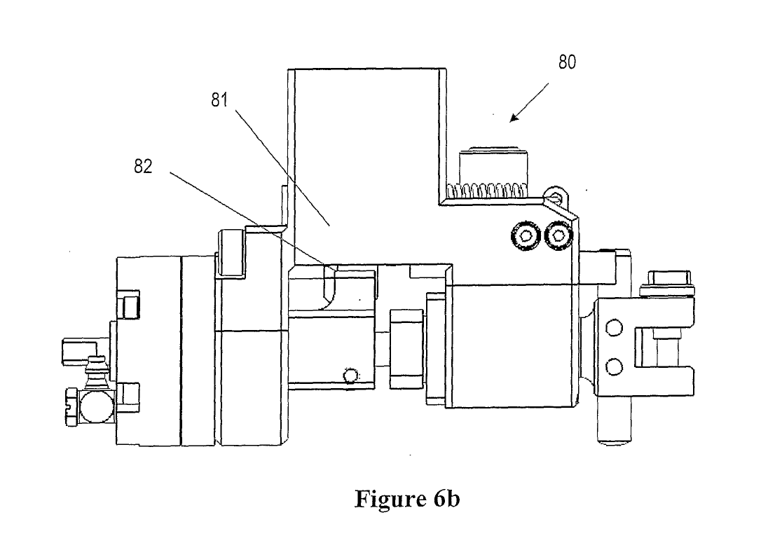

Referring to FIGS. 6a and 6b, the flipper modules (20) is mounted on a rotary plate (52) which index in counter clockwise direction by a turret motor (51), each index moved the flipper modules (20) one step ahead to the next station whereby a process is carry out to the die in the cavity pocket (92). The cavity release (57) is a cam mechanism and is mounted at location (121) and (122); when the rotary plate (52) index through these two locations, the CAM follower (79) will slide against the surface of cavity release (57) and guided the cavity lock (75) to move backward and frees the cavity holder (74), the flipping process could be achieved by activate the rotary actuator (72) on the flipper module (20) during this indexing stoppage.

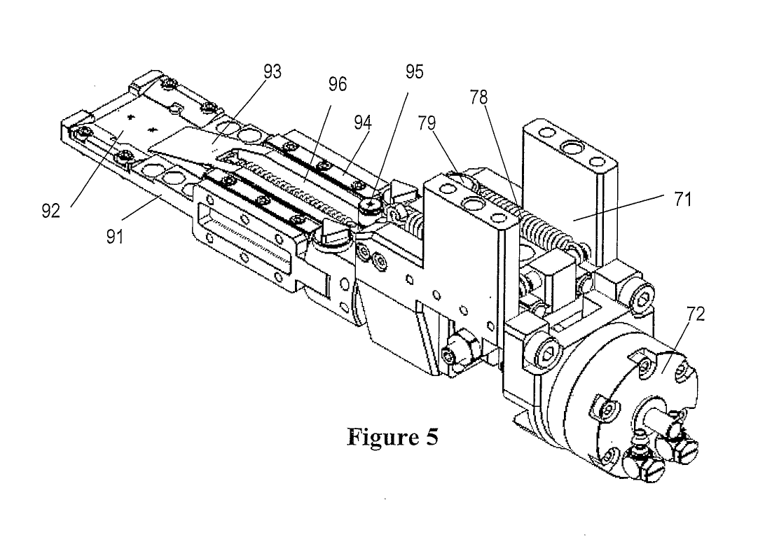

FIG. 5 shows the complete design of the flipper module (20), according to one aspect of the present invention. In one preferred embodiment, the flipper module could be separate into two portions; the flipper actuator unit (60), which is shown as FIGS. 6a and 6b and the flipper cavity unit (90) which is shown FIGS. 7a and 7b. According to one preferred embodiment, on the flipper actuator unit (60), the cavity unit (90) is assembly to the cavity holder (74) and tightens with two screws (77), the other end of the cavity holder (74) is mounted to a coupling (73) which mount in line with the rotary actuator (72); when the rotary actuator (72) is activated, it flip the cavity unit (90) 180°, hence the other surface of the die reside in the cavity pocket (92) will facing up. The cavity unit (90) maintains the horizon level to the wafer ring with the cavity lock (75) push against the lock pin (76) mount on the cavity holder (74); the cavity lock (75) used spring (78) as the return mechanism with cross roller (81) as the smooth sliding of motion. The complete flipper module (20) is mounted to the rotary plate (52) with the flipper base (71).

In one preferred embodiment, as seen in FIGS. 7a and 7b, the cavity unit (90) has two shuttle plate mounted to the cavity base (91) through cross roller (94) as the sliding mechanism and spring (96) as the return mechanism; the top cavity shuttle (93a) act as the protecting cover to prevent die flying off from the cavity pocket (92) when rotary plate (52) indexed, while cavity shuttle (93b) as the supporting base for die.

Although the operations of the method(s) herein are shown and described in a particular order, the order of the operations of each method may be altered so that certain operations may be performed in an inverse order or so that certain operations may be performed, at least in part, concurrently with other operations. Although specific embodiments of the invention have been described and illustrated, the invention is not to be limited to the specific forms or arrangements of parts so described and illustrated. The scope of the invention is to be defined by the claims appended hereto and their equivalents.

1. A die sorter for sorting semiconductor dice comprising:
a rotary turret module (19) with indexing mechanism for die sorting; wherein the rotary turret module (19) is coupled with a motor (51) for generating rotating movements;
a plurality of flipper modules (20) coupled with the rotary turret module (19) for carrying and flipping a plurality of dice; wherein the flipper module (20) comprises:
a plurality of shutter openers (55) operatively coupled to the flipper module (20) to move a cavity shuttle (93) of the flipper module (20) to an open position for pick and place and vision inspection operation of die in a cavity pocket (92) of the flipper module (20), the cavity shuttle (93) moves to a close position when the flipper module (20) flips from one station to the next station for the next operation; and
a plurality of cavity releasing means (57) operatively coupled to the flipper module (20) to unlock a cavity holder (74) of the flipper module prior to activate the flipping mechanism, wherein the cavity releasing means (57) of the flipper module (20) is a cam mechanism which is mounted on the rotary turret module (19).

2. A die sorter as claimed in claim 1, wherein the flipper module (20) further comprises a rotary actuating means (72) for enabling the flipping process of the flipper module (20).

3. A die sorter as claimed in claim 1, wherein the flipper module (20) further comprises a cavity lock (75) to secure the flipper module in horizon position as well as to prevent it from drifting during rotary plate (52) indexing movement.

4. A die sorter as claimed in claim 1, wherein the cavity unit is adjustable in order to cater for different sizes of die package.

5. A die sorter as claimed in claim 1, wherein the shutter openers (55) are operatively coupled to a motor whereby with a single rotating movement of the motor either clockwise or counter clockwise, the cavity shuttle (93) will be open.

6. A die sorter as claimed in claim 1, further comprising a plurality of cameras operatively placed at various stage of the die sorting process for visual inspection quality check.
